(19) United States
(12) Patent Application Publication
(10) Pub. No.: US 2024/0120311 A1
(43) Pub. Date: Apr. 11, 2024

(54) BONDING APPARATUS

(71) Applicant: Samsung Display Co., LTD., Yongin-si (KR)

(72) Inventors: FUTOSHI YOSHIDA, Yongin-si (KR); JONGHYUP KIM, Yongin-si (KR); JUN HA PARK, Yongin-si (KR); JINPYUNG LEE, Yongin-si (KR); DONGHYUN HAN, Yongin-si (KR)

(21) Appl. No.: 18/230,825

(22) Filed: Aug. 7, 2023

(30) Foreign Application Priority Data
Sep. 30, 2022 (KR) 10-2022-0125719

(51) Int. Cl. H01L 23/00

(52) U.S. Cl. CPC H01L 24/75; H01L 2224/75263; H01L 2224/75314; H01L 2924/401

(57) ABSTRACT

A bonding apparatus includes: a chamber including a light transmission part configured to transmit light irradiated onto a substrate on which at least one chip is disposed; and a light generation part disposed on the chamber and configured to irradiate the light. The light transmission part may include an absorption prevention layer, in which a plurality of through-holes are defined, and a light diffusion layer that diffuses the light passing through the plurality of through-holes to reduce heat generation in the light transmission part and uniformly irradiate the light passing through the light transmission part onto the substrate on which at least one chip is disposed.

This application claims priority to Korean Patent Application No. 10-2022-0125719, filed on Sep. 30, 2022, and all the benefits accruing therefrom under 35 U.S.C. § 119, the content of which in its entirety is herein incorporated by reference.

### BACKGROUND

The present disclosure herein relates to a bonding apparatus having improved reliability.

Display devices used in smart phones, televisions, monitors, and the like include various elements such as a display panel, a touch sensor, and electronic components.

The electronic components may be bonded to the display panel using a laser or ultrasonic method. Among them, the laser method is a method for allowing a substrate and the electronic components to be in contact with each other so as to bond the substrate to the electronic components through laser.

### SUMMARY

The present disclosure provides a bonding apparatus having improved reliability.

An embodiment of the invention provides a bonding apparatus including: a chamber including a light transmission part configured to transmit light irradiated onto a substrate on which at least one chip is disposed; and a light generation part disposed on the chamber and configured to irradiate the light, where the light transmission part includes an absorption prevention layer and a light diffusion layer, a plurality of through-holes through which the light passes are defined in the absorption prevention layer, and the light diffusion layer is disposed between the absorption prevention layer and the substrate to diffuse the light passing through the plurality of through-holes.

In an embodiment, the light diffusion layer may include a plurality of uneven patterns.

In an embodiment, the light diffusion layer may include: a top surface adjacent to the absorption prevention layer; and a bottom surface facing the top surface, where the plurality of uneven patterns may be provided on the bottom surface of the light diffusion layer.

In an embodiment, the light transmission part may further include an upper light diffusion layer disposed on the absorption prevention layer such that the upper light diffusion layer may be disposed between the light generation part and the absorption prevention layer.

In an embodiment, the upper light diffusion layer may include a plurality of upper uneven patterns, and the upper light diffusion layer may include: a bottom surface adjacent to the absorption prevention layer; and a top surface facing the bottom surface, where the plurality of upper uneven patterns may be provided on the top surface of the upper light diffusion layer.

In an embodiment, the bonding apparatus may further include a pressure transmission layer disposed on the at least one chip in the chamber to transmit a pressure to the at least one chip.

In an embodiment, the chamber may be connected to an external pressurizer outside the chamber, and the pressure transmission layer may be configured to transmit a pressure of air injected into the chamber from the external pressurizer to the at least one chip.

In an embodiment, the pressure transmission layer may be connected to an external pressurizer outside the chamber, and the pressure transmission layer may be expanded by air injected into the pressure transmission layer in the chamber from the external pressurizer to transmit a pressure to the at least one chip.

In an embodiment, the bonding apparatus may further include a protection film disposed between the pressure transmission layer and the at least one chip.

In an embodiment, each of the plurality of through-holes may have a hexagonal shape in a plan view.

In an embodiment, the absorption prevention layer may have a thickness greater than a thickness of the light diffusion layer.

In an embodiment, the bonding apparatus may further include a foreign substance removal layer disposed around the at least one chip.

In an embodiment of the invention, a bonding apparatus includes: a light generation part configured to irradiate light; a first chamber including a first light transmission part disposed below the light generation part to transmit the light irradiated onto a substrate on which at least one chip is disposed; and a second chamber including a second light transmission part disposed below the first chamber to transmit the light transmitted from the first light transmission part, where the second light transmission part includes a light diffusion layer configured to diffuse the light transmitted from the first light transmission part.

In an embodiment, a width of the first light transmission part in a direction parallel to a major surface of the substrate and a width of the second transmission part in the direction parallel to the major surface of the substrate may be different from each other.

In an embodiment, the width of the second light transmission part may be greater than the width of the first light transmission part.

In an embodiment, a first thickness of the first transmission part in a direction perpendicular to a major surface of the substrate may be greater than a second thickness of the second light transmission part in the direction perpendicular to the major surface of the substrate.

In an embodiment, the first light transmission part may include a first light diffusion layer configured to diffuse the light irradiated from the light generation part, and the second light transmission part may include a second light diffusion layer configured to diffuse the light diffused from the first light transmission part, and where the second light diffusion layer may include the light diffusion layer.

In an embodiment, at least one of the first light diffusion layer and the second light diffusion layer may include a plurality of uneven patterns.

In an embodiment, the bonding apparatus may further include a pressure transmission layer disposed on the at least one chip in the second chamber to transmit a pressure to the at least one chip disposed in the second chamber.

In an embodiment, the first chamber and the pressure transmission layer may be connected to an external pressurizer outside the first chamber, and the pressure transmission layer may be expanded by air injected into the pressure transmission layer in the chamber from the external pressurizer to transmit a pressure to the at least one chip.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic apparatus according to an embodiment of the invention;

FIG. 2 is an exploded perspective view of the electronic apparatus according to an embodiment of the invention.

FIG. 3 is a cross-sectional view of the display module according to an embodiment of the invention.

FIG. 4 is a cross-sectional view of a bonding apparatus according to an embodiment of the invention;

FIG. 5A is an enlarged view illustrating an area AA of FIG. 4;

FIG. 5B is an enlarged view illustrating an area BB of FIG. 5A;

FIG. 6 is an enlarged view illustrating a portion of a light transmission part according to another embodiment of the present invention;

FIG. 7 is a plan view of an absorption prevention layer according to an embodiment of the invention;

FIG. 8 is a cross-sectional view of a bonding apparatus according to another embodiment of the invention;

FIG. 9A is a cross-sectional view of a bonding apparatus according to still another embodiment of the invention; and

FIG. 9B is a cross-sectional view of a bonding apparatus according to an embodiment of the invention.

### DETAILED DESCRIPTION

Since the invention may have diverse modified embodiments, specific embodiments are illustrated in the drawings and are described in the detailed description of the invention. However, this does not limit the invention within specific embodiments and it should be understood that the invention covers all the modifications, equivalents, and replacements within the idea and technical scope of the invention.

In this specification, it will also be understood that when one component (or area, layer, portion) is referred to as being “on”, “connected to”, or “coupled to” another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of the associated listed items.

It will be understood that although the terms such as ‘first’ and ‘second’ are used herein to describe various elements, these elements should not be limited by these terms. These terms are used only to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

Unless otherwise defined, all terms (including technical and scientific terms) used herein have the same meaning as commonly understood by a person of ordinary skill in the art to which the invention belongs. Also, terms such as defined terms in commonly used dictionaries are to be interpreted as having meanings consistent with meaning in the context of the relevant art and are expressly defined herein unless interpreted in an ideal or overly formal sense.

The meaning of “include” or “comprise” specifies a property, a fixed number, a step, an operation, an element, a component or a combination thereof, but does not exclude other properties, fixed numbers, steps, operations, elements, components or combinations thereof.

Hereinafter, embodiments of the invention will be described with reference to the accompanying drawings.

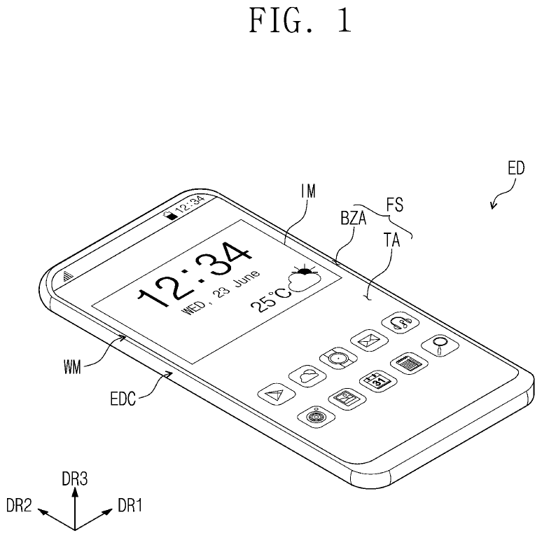

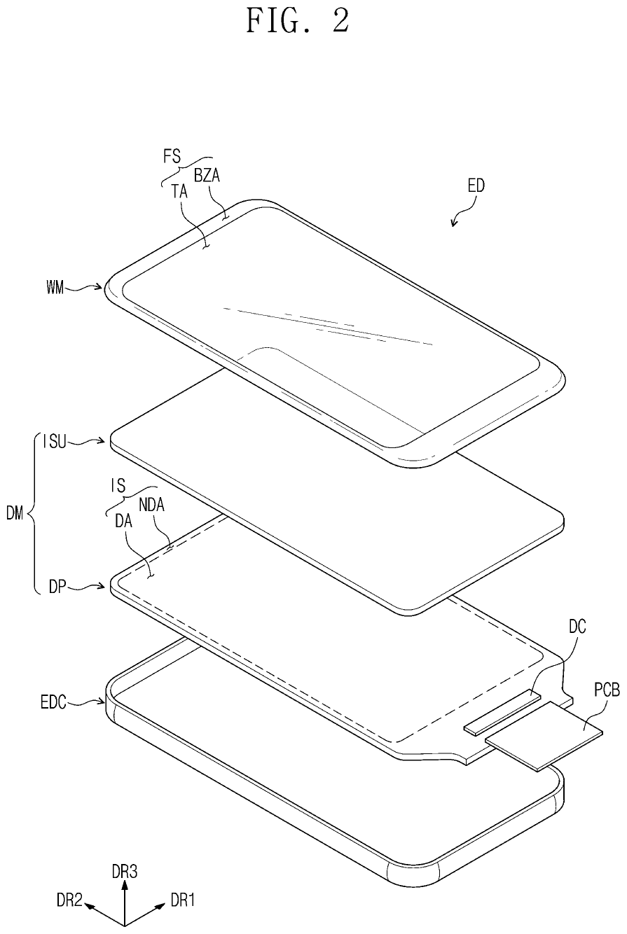

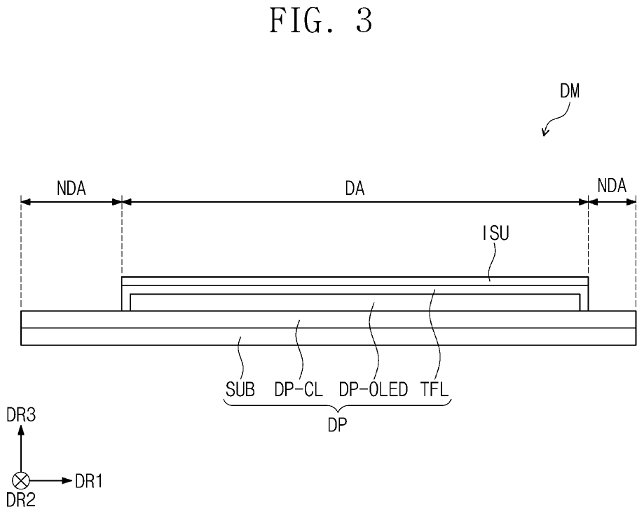

FIG. 1 is a perspective view of an electronic apparatus according to an embodiment of the invention; FIG. 2 is an exploded perspective view of the electronic apparatus according to an embodiment of the invention. FIG. 3 is a cross-sectional view of the display module according to an embodiment of the invention.

Referring to FIG. 1, an electronic apparatus DD may be an apparatus that is activated according to an electrical signal to display an image. For example, the electronic apparatus ED may include large-sized devices such as televisions, external billboards and the like, and small and medium-sized devices such as monitors, mobile phones, tablets, computers, navigation devices, game consoles, and the like. The embodiments of the electronic apparatus ED are merely examples and are not limited thereto unless departing from the concept of the present disclosure. In this embodiment, a mobile phone is illustrated as an example of the electronic apparatus ED.

The electronic apparatus ED that is in the unfolded state may have a rectangular shape that has short sides extending in a first direction DR1 and long sides extending in a second direction DR2 crossing the first direction DR1 on a plane. However, the present disclosure is not limited thereto, and the electronic apparatus ED may have various shapes such as a circular shape and a polygonal shape on the plane (i.e., in a plan view).

The electronic apparatus ED according to an embodiment may be flexible. The “flexible” means a bendable property and may include a structure that is completely folded to a few nanometer. For example, the flexible electronic apparatus ED may include a curved apparatus or a foldable apparatus. However, the embodiment of the invention is not limited thereto, and the electronic apparatus ED includes a rigid property in another embodiment.

The electronic apparatus ED may display an image IM in a third direction DR3 on a display surface parallel to each of first and second directions DR1 and DR2. The image IM provided by the electronic apparatus ED may include a still image as well as a dynamic image. FIG. 1A illustrates a watch window and icons as an example of the image IM.

The display surface on which the image IM is displayed may correspond to a front surface of the electronic apparatus ED. Although FIG. 1 illustrates a planar display surface, a display surface of the electronic apparatus ED may include a curved surface that is bent from at least one side of the planar surface.

A front surface (or top surface) and a rear surface (or bottom surface) of each of members constituting the electronic apparatus ED may be opposed to each other in the third direction DR3, and a normal direction of each of the front and rear surfaces may be substantially parallel to the third direction DR3. A spaced distance between the front surface and the rear surface defined along the third direction DR3 may correspond to a thickness of the member (or unit).

Referring to FIGS. 1 and 2, the electronic apparatus ED may include a window WM, a display module DM, an electronic component DC, a circuit board PCB, and a case EDC. The window WM and the case EDC may be coupled to each other to define an outer appearance of the electronic apparatus ED and may provide an internal space that accommodates the components of the electronic apparatus ED.

The window WM may be disposed on the display module DM. The window WM may have a shape corresponding to a shape of a display module DM. The window WM may cover the entire outside of the display module DM to protect the display module DM from an external impact and scratch.

The window WM may include an optically transparent insulating material. For example, the window WD may include a glass substrate or a polymer substrate. The window WM may have a single-layered or multi-layered structure. The window WIN may further include functional layers such as an anti-fingerprint layer, a phase control layer, and a hard coating layer, which are disposed on a transparent substrate.

The front surface FS of the window WM may include a transmission area TA and a bezel area BZA. The transmission area TA of the window WM may be an optically transparent area. The window WM may transmit the image IM provided by the display module DM through the transmission area TA, and the user may visually recognize the image IM.

The bezel area BZA of the window WM may be provided as an area on which a material having a predetermined color is printed. The bezel area BZA of the window WM may prevent a component of the display module DM disposed to overlap the bezel area BZA from being seen to the outside.

The bezel area BZA may surround the transmission area TA. A shape of the transmission area TA may be substantially defined by the bezel area BZA. For example, the bezel area BZA may be disposed outside the transmission area TA to surround the transmission area TA. However, this is merely an example. For example, the bezel area BZA may be adjacent to only one side of the transmission area TA or be omitted. Also, the bezel area BZA may be disposed on an inner surface of the electronic apparatus ED instead of the front surface thereof.

The display module DM may be disposed between the window WM and the case EDC. The display module DM may include a display panel DP and an input sensor ISU.

The display panel DP may display the image IM in response to an electrical signal. The display panel DP according to an embodiment of the invention may be an emission type display panel, but is not limited thereto. For another example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include a quantum dot, a quantum rod, and the like. Hereinafter, the display panel DP is described as an organic light emitting display panel.

The image IM provided by the electronic apparatus ED may be displayed on the front surface IS of the display panel DP. The front surface IS of the display panel DP may include a display area DA and a non-display area NDA. The display area DA may be activated according to the electrical signal to display the image IM. According to an embodiment, the display area DA of the display panel DP may correspond to the transmission area TA of the window WM.

In this specification, that “area/portion and area/portion corresponds to each other” means “overlapping with each other”, but is not limited to having the same area and/or the same shape.

The non-display area NDA may be adjacent to the outside of the display area DA. For example, the non-display area NDA may surround the display area DA. However, the embodiment of the invention is not limited thereto, and the non-display area NDA may be defined in various shapes.

The non-display area NDA may be an area on which a driving circuit or driving line for driving elements disposed on the display area DA, various signal lines providing electrical signals, and pads are disposed. The non-display area NDA of the display panel DP may correspond to the bezel area BZA of the window WM. The components of the display panel DP disposed in the non-display area NDA may be prevented from being visually recognized to the outside by the bezel area BZA.

Referring to FIGS. 2 and 3, the display panel DP may include a base substrate SUB, a circuit element layer DP-CL, a display element layer DP-OLED, and an insulating layer TFL.

The base substrate SUB may be a glass substrate, a metal substrate, or a polymer substrate. However, the embodiment of the invention is not limited thereto. For another example, the base substrate SUB may be an inorganic layer, an organic layer, or a composite layer.

The circuit element layer DP-CL may be disposed on the base substrate SUB. The circuit element layer DP-CL may include at least one intermediate insulating layer and a circuit element. The intermediate insulating layer includes at least one intermediate inorganic film and at least one intermediate organic film. The circuit element may include signal lines, a pixel driving circuit, and the like.

The display element layer DP-OLED may be disposed on the circuit element layer DP-CL. The display element layer DP-OLED may include a plurality of organic light emitting diodes. The display element layer DP-OLED may further include an organic layer such as a pixel defining layer.

The insulating layer TFL may cover layer the display element layer DP-OLED. The insulating layer TFL may be a thin film encapsulation layer. The insulation layer TFE may protect the display element layer DP-OLED against foreign substances such as moisture, oxygen, and dust particles. However, this is merely an example, and an encapsulation substrate may be provided instead of the insulating layer TFL. In this case, the encapsulation substrate may face the base substrate SUB, and the circuit element layer DP-CL and the display element layer DP-OLED may be disposed between the encapsulation substrate and the base substrate SUB.

The input sensor ISU may be disposed between the window WM and the display panel DP. The input sensor ISU may sense various types of external inputs such as force, a pressure, a temperature, and light provided from the outside. For example, the input sensor ISU may sense a touch of the user's body or a pen provided from the outside of the electronic apparatus ED, or an input (e.g., hovering) applied close to the electronic apparatus ED.

Referring again to FIG. 2, the electronic component DC may overlap the non-display area NDA and be disposed on the display panel DP. However, the embodiment of the invention is not limited thereto, and the electronic component DC may be disposed on a printed circuit board in another embodiment. The electronic component DC may transmit a driving signal to the circuit element layer DP-CL of the display panel DP based on a control signal transmitted from the circuit board PCB. The electronic component DC according to an embodiment of the invention may be referred to as a driving chip or a chip.

The display panel DP according to an embodiment of the invention may include a pad electrically connected to the display element layer DP-OLED, and the electronic component DC may include a bump that is in electrical contact with the pad. Particularly, the pad of the display panel DP and the bump of the electronic component DC according to an embodiment of the invention may have a structure connected through a separate conductive material.

The circuit board PCB may be connected to one end of the display panel DP extending in the first direction DR1. The circuit board PCB may generate electrical signals provided to the display panel DP. For example, the circuit board PCB may include a timing controller that generates signals provided to a driving chip DC in response to control signals received from the outside. The timing controller may be mounted on the circuit board PCB in the form of an integrated chip. The circuit board PCB may be electrically bonded to the base substrate SUB of the display panel DP.

As an example of the invention, at least a portion of the non-display area NDA of the display panel DP may be bent. A portion of the display panel DP to which the circuit board PCB is connected may be bent so that the circuit board PCB faces a rear surface of the display panel DP. The circuit board PCB may be disposed and assembled to overlap the rear surface of the display panel DP on the plane (i.e., in a plan view). However, the display panel DP and the circuit board PCB are not limited thereto, and the display panel DP and the circuit board PCB may be connected through a flexible circuit board connected to ends of the display panel DP and the circuit board MB, respectively in another embodiment.

The case EDC may be disposed under the display panel DP to accommodate the display panel DP. The case EDC may include glass, plastic, or metal material having relatively high rigidity. The case EDC may protect the display panel DP by absorbing an impact applied from the outside or preventing foreign substances/moisture from being penetrated into the display panel DP.

In addition, the electronic apparatus ED may further include an electronic module including various functional modules for operating the display panel DP and a power supply module for supplying power to the electronic apparatus ED. For example, the electronic apparatus ED may include a camera module as an example of an electronic module.

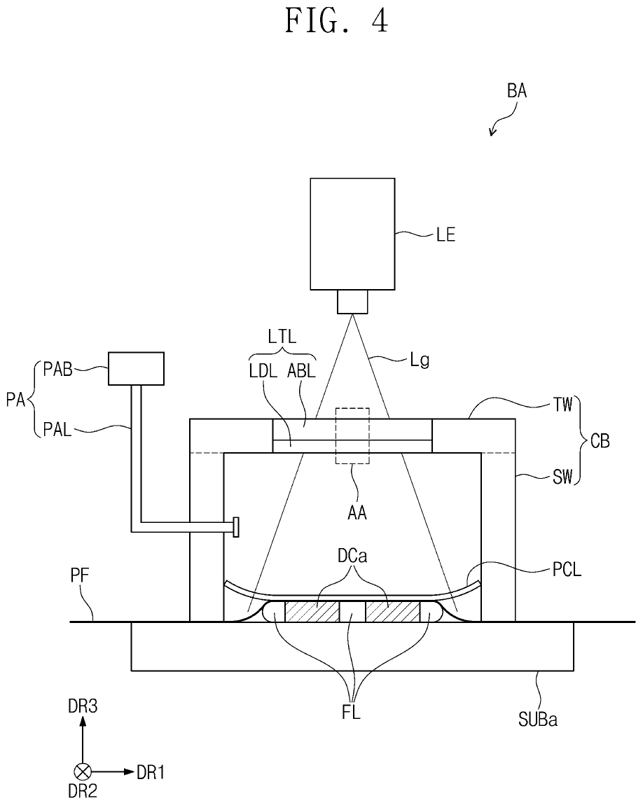

According to an embodiment of the invention, the driving chip DC may be bonded to the base substrate SUB through a laser bonding manner. Hereinafter, a bonding apparatus BA (see FIG. 4) for bonding the driving chip DC to the base substrate SUB will be described in detail.

FIG. 4 is a cross-sectional view of a bonding apparatus according to an embodiment of the invention.

Referring to FIG. 4, a bonding apparatus BA according to an embodiment of the invention may be a laser (or light) bonding apparatus that performs a bonding operation using a laser (or light). The bonding apparatus BA may include a light generation part LE, a chamber CB, a pressure transmission layer PCL, a protection film PF, and an external pressurizer PA.

The chamber CB may be disposed below the light generation part LE. Specifically, a substrate SUBa may be disposed below the chamber CB and adjacent to the chamber CB. The substrate SUBa may have a plane defined in a first direction DR1 and a second direction DR2 crossing the first direction DR1. Hereinafter, a direction substantially perpendicularly crossing the plane defined by the first and second directions DR1 and DR2 is defined as a third direction DR3. In this specification, the term “viewed from the plane” or “in a plan view” may mean a state viewed from the third direction D3. According to an embodiment of the invention, the substrate SUBa may include the base substrate SUB illustrated in FIG. 3. However, the embodiment of the invention is not limited thereto, and the circuit board PCB (see FIG. 2) may be provided as a configuration to which a chip DCa is bonded in another embodiment.

At least one chip DCa to be bonded may be disposed on the substrate SUBa. According to an embodiment of the invention, the chip DCa may include the electronic component DC (see FIG. 2) of the electronic apparatus ED (see FIG. 2). However, the embodiment of the invention is not limited thereto, and the chip DCa may include a light emitting diode (LED) chip or the like in another embodiment.

According to an embodiment of the invention, a plurality of chips DCa may be disposed on the substrate SUBa. However, the embodiment of the invention is not limited thereto, and one chip DCa may be disposed on the substrate SUBa in another embodiment. Although not shown, a solder may be provided between the substrate SUBa and at least one chip DCa. The solder is configured to bond the substrate SUBa to the chip DCa disposed on the substrate SUBa and may have a ball shape. For example, the solder may include lead (Pb), tin (Sn), or the like, but is not limited thereto.

According to an embodiment of the invention, a foreign material removal film FL may be applied on the substrate SUBa. Specifically, the bonding apparatus BA may further include the foreign material removal film FL disposed around the chip DCa. The foreign material removal film FL may prevent oxidation from occurring when the solder disposed between the substrate SUBa and the chip DCa is heated and melted by irradiation of light Lg. Although not shown, the foreign matter removal film FL is not limited to being disposed on a side surface of the chip DCa, and may be disposed between the chip DCa and the substrate SUBa to remove an oxidized material of the solder that is heated and melted by the irradiation of the light Lg in another embodiment.

The light generation part LE serves to emit the light Lg to irradiate the light Lg to the substrate SUBa on which at least one chip DCa is disposed. Although not shown, the light generation part LE may include a laser generator that generates the light Lg, a scanner that controls a scanning path of the light Lg generated from the laser generator, and a laser head that emits the light Lg toward the substrate SUBa.

The light generation part LE according to an embodiment of the invention may emit the light Lg having a wavelength in an infrared or near-infrared range. The light Lg having the wavelength in the infrared or near-infrared range may have a strong thermal effect and thus may be effectively used for the light (or laser) bonding that requires temperature rise and control in a short time. For example, the light generation part LE may emit the light Lg having a wavelength of approximately 800 nanometers (nm) to approximately 1,050 nm and an output of about 100 watts (W) to about 200 W. However, the embodiment of the invention is not limited thereto, and the light generation part LE may emit light Lg having a wavelength in various ranges. Although not shown in the drawings, the light generation part LE may further include other optical elements in addition to the above-described optical elements.

An external pressurizer PA may be disposed outside the chamber CB to increase pressure inside the chamber CB. The external pressurizer PA may include a pressing body PAB and a pressing line PAL. The pressing body PAB may be, for example, a pressurized air generation part. Air is generated from the pressing body PAB, and the generated air may be injected into the chamber CB along the pressing line PAL. Although not shown, the pressing line PAL may include a pressing controller that controls whether the air is injected (that is, controls an internal pressure). A pressure inside the chamber CB may be adjusted to about 0.5 megapascals (MPa) or more and about 1 MPa or less by the external pressurizer PA.

The chamber CB may provide an inner space, and a chip DCa disposed on the substrate SUBa, a pressure transmission layer PCL, and a protection film PF may be provided in the inner space of the chamber CB.

The pressure transmission layer PCL may be disposed on the chip DCa. According to an embodiment of the invention, the pressure transmission layer PCL may receive air injected into the chamber CB from the external pressurizer (“PA”) disposed outside the chamber CB to transmit the pressure of the injected air to the chip DCa. The pressure transmission layer PCL may transmit a uniform pressure to the chip DCa in a direction of the substrate SUBa, i.e., in an opposite direction to the third direction DR3 by the internal air pressure of the chamber CB. As the pressure transmission layer PCL and the pressure transmission surface that is in contact with the chip DCa may be maintained in flatness with respect to the plane defined by the first and second directions DR1 and DR2, the bonding apparatus BA may uniformly apply the pressure to the chip DCa in the direction of the substrate SUBa. Therefore, since the chip DCa receives the uniform pressure in the direction of the substrate SUBa, bonding quality between the substrate SUBa and the chip DCa may be improved. The pressure transmission layer PCL may be made of a material that well transmits the light Lg irradiated from the light generation part LE. For example, the pressure transmission layer PCL may be made of rubber or silicon. However, the configuration of the pressure transmission layer PCL is not limited thereto.

The protection film PF may be disposed between the pressure transmission layer PCL and the chip DCa. The protection film PF may include low-density polyethylene (“LDPE”) and may have high transparency, flexibility, and chemical resistance. The protection film PF may serve to protect the pressure transmission layer PCL from external moisture and foreign substances, which are introduced through the substrate SUBa. The protection film PF may be formed by an adhesive coating method, a self-adhesive method, and a supply/recovery roll.

The chamber CB may include a sidewall SW and an upper wall TW, which define the inside of the chamber CB. The sidewall SW may be parallel to the third direction DR3, and the upper wall TW may be parallel to the first and second directions DR1 and DR2. In the chamber CB, a pressure greater than a certain level exists by the external pressurizer PA. Therefore, each of the sidewall SW and the upper wall TW may be made of a solid material to withstand a pressure of a certain intensity or more. For example, each of the sidewall SW and the upper wall TW may include a metal material. As an example of the invention, each of the sidewall SW and the upper wall TW may include stainless steel, aluminum, or an alloy thereof.

According to an embodiment of the invention, the chamber CB may include a light transmission part LTL that transmits the light Lg toward at least one chip DCa. Specifically, the upper wall TW of the chamber CB may include the light transmission part LTL. The light transmission part LTL may be disposed between the substrate SUBa and the light generating part LE and may be made of a material that is transparent that is enough to transmit the light Lg irradiated to the substrate SUBa. As the light Lg transmitted through the light transmission part LTL is irradiated to the at least one chip DCa disposed on the substrate SUBa, heat generated by the light Lg may melt the solder so that the chip DCa is bonded to the substrate SUBa. A thickness of the light transmission part LTL in the third direction DR3 may be the same as a thickness of the upper wall TW in the third direction DR3. However, the embodiment of the invention is not limited thereto. For another example, the thickness of the light transmission part LTL may be less than the thickness of the upper wall TW.

The light transmission part LTL may include an absorption prevention layer ABL that prevents light from being absorbed therein and a light diffusion layer LDL disposed between the absorption prevention layer ABL and the substrate SUBa to diffuse the light Lg passing through the absorption prevention layer ABL. Details of the absorption prevention layer ABL and the light diffusion layer LDL will be described later.

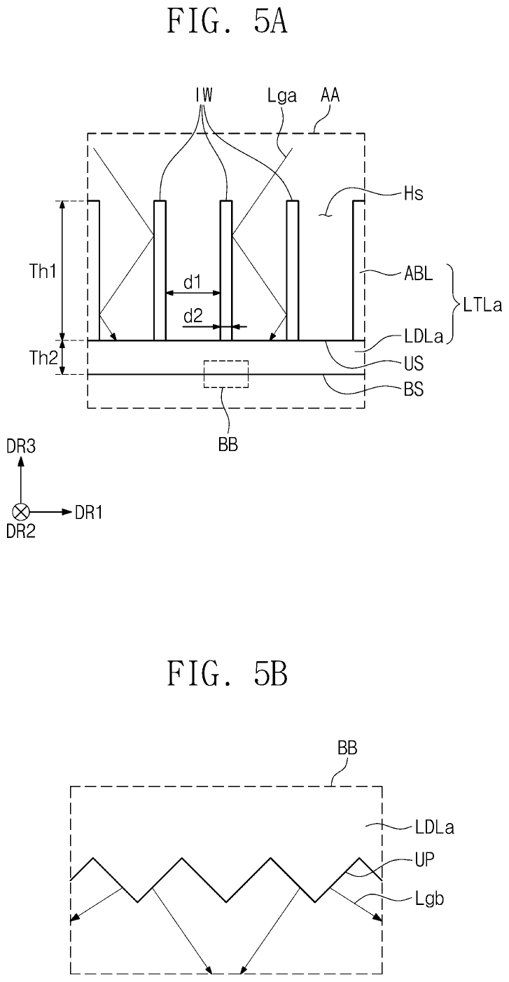

FIG. 5A is an enlarged view illustrating an area AA of FIG. 4. Particularly, FIG. 5A is an enlarged view illustrating a portion of a light transmission part LTLa. FIG. 5B is an enlarged view illustrating an area BB of FIG. 5A. Particularly, FIG. 5B is an enlarged view illustrating a portion of a light diffusion layer LDLa.

Referring to FIG. 5A, the absorption prevention layer ABL may include a plurality of inner walls IW. According to an embodiment of the invention, a plurality of through-holes Hs may be defined by the plurality of inner walls IW in the absorption prevention layer ABL. The plurality of through-holes Hs may transmit the light Lg irradiated from the light generation part LE (see FIG. 4) to a light diffusion layer LDLa.

The light Lga incident to the light transmission part LTLa may collide with the plurality of inner walls IW and then be reflected. The reflected light Lga may be incident toward the light diffusion layer LDLa disposed under the absorption prevention layer ABL. An amount of light Lga that is incident toward the plurality of through-holes Hs to collide with the plurality of inner walls IW and then is reflected may vary according to an incident angle of the incident light Lga. The incident angle is measured with respect to the direction opposite to the third direction DR3. For example, as the incident angle of the incident light Lga increases, the amount of light Lga that is incident toward the plurality of through-holes Hs to collide with the plurality of inner walls IW and then is reflected may decrease. Each of the plurality of inner walls IW may be made of a material having a high light reflectance to prevent light from being absorbed by inner walls IW, thereby totally reflecting all incident light. For example, the inner wall IW may be made of glass or polished aluminum (Al). Particularly, the polished aluminum may reflect about 90% of the light incident on the surface. In addition, like the polished aluminum, a separate reflective film may be applied or deposited on the plurality of inner walls IW to improve reflectivity. As the separate reflective film is applied or deposited, light attenuation due to the absorption may be prevented or reduced even if the irradiated light Lga is reflected several times inside the wall surface when passing through the plurality of through-holes Hs.

A width of each of the through-holes Hs in the first direction DR1 may be defined as a first width d1, and a width of each of the inner walls IW in the first direction DR1 may be defined as a second width d2. The first width d1 and the second width d2 may be different from each other. According to one embodiment of the invention, the first width d1 may be greater than the second width d2. Since a pressure of a certain level or more exists inside the chamber CB (see FIG. 4), it is desirable to design the second width d2 to have a size to withstand the pressure of the certain level or more. That is, the second width d2 may be set differently according to the internal pressure of the chamber CB. The plurality of through-holes Hs are illustrated as having the same width, but are not limited thereto, and the plurality of through-holes Hs may have different widths in another embodiment. A thickness Th1 of the absorption prevention layer ABL and a thickness Th2 of the light diffusion layer LDLa in the third direction DR3 (i.e., thickness direction of the light transmission part) may be different from each other. According to an embodiment of the invention, the thickness Th1 of the absorption prevention layer ABL may be greater than the thickness Th2 of the light diffusion layer LDLa.

The amount of light Lga passing through the plurality of through-holes Hs may vary according to the number of through-holes Hs and the first width d1. As the light Lga is transmitted through the plurality of through-holes Hs, the amount of light Lga absorbed by the absorption prevention layer ABL may be reduced. Thus, the light Lga may be absorbed by the absorption prevention layer ABL to prevent transmission efficiency of the light Lga from being deteriorated, and since the amount of light Lga absorbed is reduced, heat generation of the light transmission part LTLa may be reduced.

Referring to FIGS. 5A and 5B, the light diffusion layer LDLa may include a top surface US adjacent to the absorption prevention layer ABL and a bottom surface BS facing the top surface US. According to an embodiment of the invention, the light diffusion layer LDLa may include a plurality of uneven patterns UP. Specifically, the plurality of uneven patterns UP may be provided on the bottom surface BS of the light diffusion layer LDLa.

The light diffusion layer LDLa may be made of a single transparent material, for example, a glass plate or a transparent resin. The light diffusion layer LDLa may include a separate light diffusion agent to diffuse the light Lga incident to the light diffusion layer LDLa. For example, the light diffusion layer LDLa may include an inorganic material such as barium sulfate, calcium carbonate, or titanium oxide, and an organic material such as glass and acrylic resins, styrene, styrene-acrylic resins, and melamine resins.

As the plurality of uneven patterns UP are provided on the bottom surface BS of the light diffusion layer LDLa, light Lga incident to the light diffusion layer LDLa may be diffused on the bottom surface BS. When light Lga passes through different media such as air and glass, the light Lga is refracted at an interface between the two media. When the light Lga passing through the light diffusion layer LDLa is incident onto the plurality of uneven patterns UP made of the transparent material, the light Lga may be refracted and diffused to the outside (i.e., under the uneven patterns UP) of the plurality of uneven patterns UP. A degree of refraction and diffusion of the light Lga may vary according to a shape of each of the plurality of uneven patterns UP and a refractive index of the light diffusion layer LDLa. As the light transmission part LTLa includes the light diffusion layer LDLa on which the plurality of uneven patterns UP are provided, the light Lga passing through the light diffusion layer LDLa may be uniformly irradiated onto the substrate SUBa (see FIG. 4) on which the chip DCa (see FIG. 4) is disposed.

Thus, the bonding reliability between the substrate SUBa and the chip DCa may be improved. Particularly, when the plurality of chips DCa are bonded on the substrate SUBa, an amount of light Lga irradiated according to the position of the chip DCa may be prevented from varying and may be applied with uniform intensity to the plurality of chips DCa.

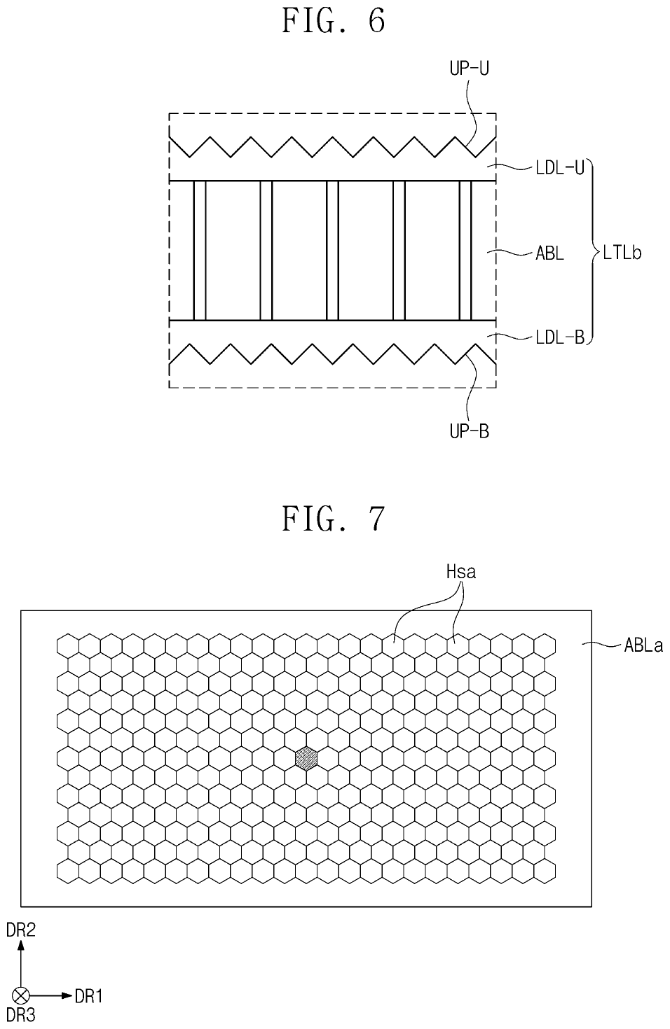

FIG. 6 is an enlarged view illustrating a portion of a light transmission part according to another embodiment of the present invention.

Referring to FIG. 6, a light transmission part LTLb may include a lower light diffusion layer LDL-B, an absorption prevention layer ABL, and an upper light diffusion layer LDL-U.

The lower light diffusion layer LDL-B may include a plurality of lower uneven patterns UP-B. The lower light diffusion layer LDL-B may include a top surface adjacent to the absorption prevention layer ABL and a bottom surface facing the top surface. According to an embodiment of the invention, the plurality of lower uneven patterns UP-B may be provided on the bottom surface of the lower light diffusion layer LDL-B.

The upper light diffusion layer LDL-U may be disposed on the absorption prevention layer ABL. The upper light diffusion layer LDL-U may include a plurality of upper uneven patterns UP-U. The upper light diffusion layer LDL-U may include a bottom surface adjacent to the absorption prevention layer ABL and a top surface facing the bottom surface. According to an embodiment of the invention, the plurality of upper uneven patterns UP-U may be provided on the top surface of the upper light diffusion layer LDL-U.

Compared to the light transmission part LTLa illustrated in FIG. 5A, the light transmission part LTLb illustrated in FIG. 6 may further include an upper light diffusion layer LDL-U including the plurality of upper uneven patterns UP-U. As illustrated in the drawings, as the plurality of upper uneven patterns UP-U are provided on the top surface of the upper light diffusion layer LDL-U, light Lg (see FIG. 4) incident onto the upper light diffusion layer LDL-U may be diffused. A degree to which the light Lg is refracted and diffused may vary according to the shape and material of the plurality of upper uneven patterns UP-U. The light diffused from the upper light diffusion layer LDL-U may be uniformly incident onto the absorption prevention layer ABL.

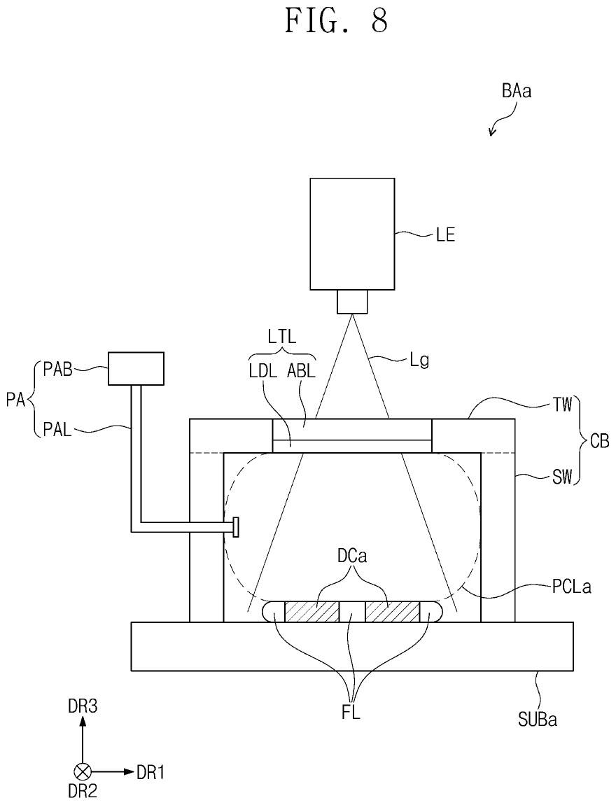

FIG. 7 is a plan view of an absorption prevention layer according to an embodiment of the invention.

Referring to FIG. 7, an absorption prevention layer ABLa may include a plurality of through-holes Hsa. According to an embodiment of the invention, each of the plurality of through-holes Hsa may have a hexagonal shape on the plane (i.e., in a plan view). That is, each of the plurality of through-holes Hsa may be provided in a hexagonal shape on the plane, and the absorption prevention layer ABLa may have a honeycomb structure. The plurality of through-holes Hs according to an embodiment have the hexagonal shape on the plane, but are not limited thereto. For another example, each of the plurality of through-holes Hs may have a polygonal shape such as a triangular shape, a quadrangular shape, or a circular shape in a plan view.

The honeycomb structure of the absorption prevention layer ABLa according to an embodiment of the invention is a stable structure that is capable of securing a maximum space with minimum materials. The honeycomb structure is very stable, which is resistant to a pressure, i.e., force that presses downward from an upper side. In the chamber CB illustrated in FIG. 4, a pressure greater than a predetermined level exist in the external pressurizer PA. The absorption prevention layer ABLa may withstand pressure in the chamber CB as the absorption prevention layer ABLa includes the hexagonal shape on the plane, i.e., the honeycomb structure.

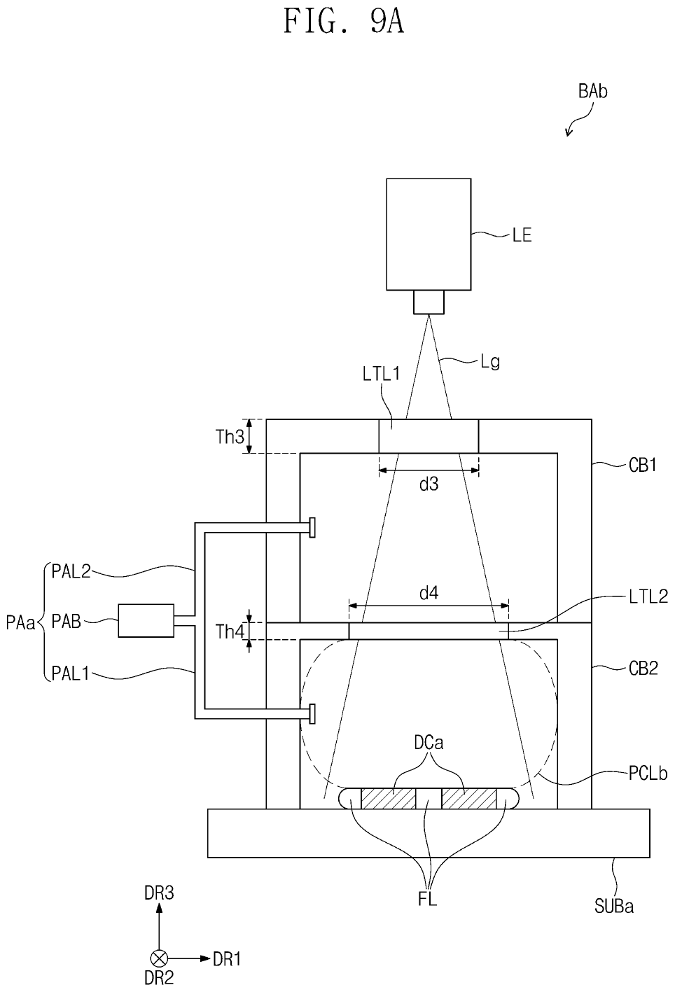

FIG. 8 is a cross-sectional view of a bonding apparatus according to another embodiment of the invention. Hereinafter, the same reference numeral may be given to components that are the same as those of FIGS. 1 to 7, and their detailed descriptions will be omitted.

Referring to FIG. 8, a chamber CB may provide an inner space, and a chip DCa disposed on a substrate and a pressure transmission layer PCLa may be provided in the inner space of the chamber CB. An external pressurizer PA that injects air into the pressure transmission layer PCLa may be disposed outside the chamber CB.

According to an embodiment of the invention, the pressure transmission layer PCLa may be disposed on the chip DCa. The pressure transmission layer PCLa may be connected to the external pressurizer PA disposed outside the chamber CB, and the pressure transmission layer PCLa may be expanded by air injected into the pressure transmission layer PCLa from the external pressurizer PA so that a pressure is transmitted to the chip DCa. Specifically, the pressure transmission layer PCLa may be expanded to be in contact with the sidewall SW, the upper wall TW, the light transmission part LTL, and the chip DCa of the chamber CB, thereby transmitting a uniform pressure to the chip DCa in the direction of the substrate SUBa, i.e., the direction opposite to the third direction DR3. The pressure transmission layer PCLa may include a material having elasticity so as to be expanded by air injected into the pressure transmission layer PCLa. For example, a thin film having elasticity may include natural rubber, synthetic rubber, or a metal plate.

The expanded pressure transmission layer PCLa may provide a pressing surface that is in contact with all of the plurality of chips DCa. As the pressure transmission layer PCLa and the pressure transmission surface that is in contact with the plurality of chips DCa is maintained in flatness with respect to the plane defined by the first and second directions DR1 and DR2, the bonding apparatus BA may uniformly apply the pressure to the chips DCa in the direction of the substrate SUBa. Therefore, since the chip DCa receives the uniform pressure in the direction of the substrate SUBa, bonding quality between the substrate SUBa and the chip DCa may be improved. Since the light Lg emitted from the light generation part LE passes through the expanded pressure transmission layer PCLa and is irradiated onto the substrate SUBa, the pressure transmission layer PCLa may be made of a material that transmits the light Lg well. For example, the pressure transmission layer PCLa may be made of transparent rubber or transparent silicon. However, the configuration of the pressure transmission layer PCLa is not limited thereto.

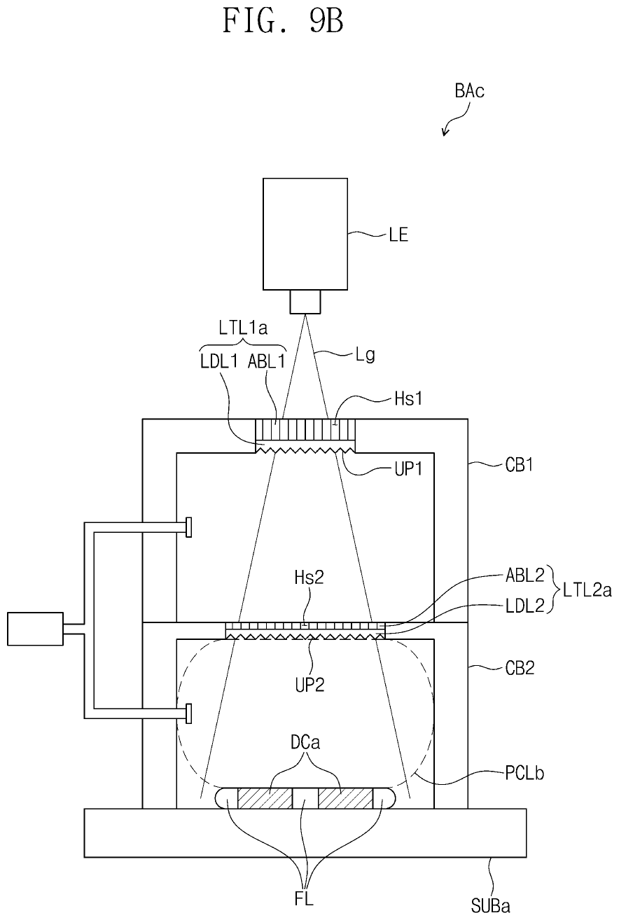

FIG. 9A is a cross-sectional view of a bonding apparatus according to still another embodiment of the invention.

Referring to FIG. 9A, a bonding apparatus BAb may include a light generation part LE, a first chamber CB1, a second chamber CB2, a pressure transmission layer PCLb, and an external pressurizer PAa. In the bonding apparatus BAb according to an embodiment of the invention, light Lg emitted from the light generation part LE may pass through the first light transmission part LTL1 provided in the first chamber CB1 and the second light transmission part LTL2 provided in the second chamber CB2 and then be irradiated onto the substrate SUBa on which at least one chip DCa is disposed.

The external pressurizer PAa may be disposed outside the first chamber CB1 and the second chamber CB2 to increase in pressure inside the first chamber CB1 and the pressure transmission layer PCLb. The external pressurizer PAa may include a pressing body PAB, a first pressing line PAL1, and a second pressing line PAL2. The pressing body PAB may be, for example, a pressurized air generation part. Air may be generated from the pressing body PAB, and the generated air may be injected into the pressure transmission layer PCLb along the first pressing line PAL1 and also may be injected into the first chamber CBT along the second pressing line PAL2. Although not shown, each of the first pressing line PAL1 and the second pressing line PAL2 may include a pressing controller that controls whether the air is injected (that is, controls an internal pressure). The internal pressures of the first chamber CBT and the pressure transmission layer PCLb may be maintained equal to each other by the external pressurizer PAa. However, the embodiment of the invention is not limited thereto, and the internal pressures of the first chamber CBT and the pressure transmission layer PCLb may be maintained differently from each other by the external pressurizer PAa in another embodiment. The pressure inside each of the first chamber CBT and the pressure transmission layer PCLb may be adjusted to about 0.5 MPa or more and about 1 MPa or less by the external pressurizer PAa.

The first chamber CBT may be disposed adjacent to the light generation part LE. Specifically, the first chamber CBT may be disposed between the second chamber CB2 and the light generation part LE. The first chamber CBT may include a first light transmission part LTL1 through which the light Lg emitted from the light generating part LE is transmitted. Although not shown, the first light transmission part LTL1 may include a separate light diffusion agent that diffuses the light Lg incident to the first light transmission part LTL1. For example, the first light transmission part LTL1 may include an inorganic material such as barium sulfate, calcium carbonate, and titanium oxide, and an organic material such as glass and acrylic resins, styrene, styrene-acrylic resins, and melamine resins.

The first chamber CB1 may be made of a solid material to withstand the internal pressure of the first chamber CBT by the external pressurizer PAa. For example, the first chamber CBT may include a metal material. As an example of the invention, the first chamber CBT may include stainless steel, aluminum, or an alloy thereof.

The second chamber CB2 may be disposed below the first chamber CBT. Specifically, the second chamber CB2 may be disposed between the first chamber CBT and the substrate SUBa. The second chamber CB2 may include a second light transmission part LTL2 that transmits the light Lg transmitted from the first light transmission part LTL1. Although not shown, the second light transmission part LTL2 may include a separate light diffusing agent that diffuses the light Lg incident to the second light transmission part LTL2. For example, the second light transmission part LTL2 may include an inorganic material such as barium sulfate, calcium carbonate, and titanium oxide, and an organic material such as glass and acrylic resins, styrene, styrene-acrylic resins, and melamine resins as the light diffusion agent. Although not shown, the second light transmission part LTL2 may include a light diffusion layer LDL (see FIG. 4). The second light transmission part LTL2 may include a light diffusion layer LDL that diffuses the light Lg incident to the second light transmission part LTL2, and thus, the diffused light Lg may be uniformly irradiated onto the chip DCa.

The second chamber CB2 may provide an inner space, and a chip DCa disposed on the substrate SUBa and a pressure transmission layer PCLb disposed on the chip DCa may be provided in the inner space of the second chamber CB2. Although not shown, a protection film PF (see FIG. 4) may be disposed between the pressure transmission layer PCLb and the chip DCa to protect the chip DCa and the pressure transmission layer PCLb from external moisture and foreign substances.

According to an embodiment of the invention, the pressure transmission layer PCLb may be connected to the external pressurizer PAa disposed outside the first chamber CBT and the second chamber CB2, and the pressure transmission layer PCLb may be expanded by air injected into the pressure transmission layer PCLb from the external pressurizer PAa so that a pressure is transmitted to the chip DCa. Specifically, the pressure transmission layer PCLb may be expanded to be in contact with the inner sidewall SW, the second light transmission part LTL2, and the chip DCa of the chamber CB, thereby transmitting a uniform pressure to the chip DCa in the direction of the substrate SUBa, i.e., the direction opposite to the third direction DR3. The pressure transmission layer PCLb may include a material having elasticity so as to be expanded by air injected into the pressure transmission layer PCLb. For example, The pressure transmission layer PCLb as a thin film having elasticity may include natural rubber, synthetic rubber, or a metal plate.

The expanded pressure transmission layer PCLb may provide a pressing surface that is in contact with all of the plurality of chips DCa. As the pressure transmission layer PCLb and the pressure transmission surface that is in contact with the plurality of chips DCa is maintained in flatness with respect to the plane defined by the first and second directions DR1 and DR2, the bonding apparatus BAb may uniformly apply the pressure to the chips DCa in the direction of the substrate SUBa. Therefore, since the chip DCa receives the uniform pressure in the direction of the substrate SUBa, bonding quality between the substrate SUBa and the chip DCa may be improved. The pressure transmission layer PCLb may be made of a material that well transmits the light Lg irradiated from the light generation part LE. For example, the pressure transmission layer PCLb may be made of transparent rubber or transparent silicon. However, the configuration of the pressure transmission layer PCLb is not limited thereto.

A thickness Th3 of the first light transmission part LTL1 and a thickness Th4 of the second light transmission part LTL2 in the thickness direction (i.e., the third direction DR3) may be different from each other. According to an embodiment of the invention, the thickness Th3 of the first light transmission part LTL1 may be greater than the thickness Th4 of the second light transmission part LTL2. Specifically, the thickness Th3 of the first light transmission part LTL1 may increase to withstand a pressure of a certain level or more because the pressure of the certain level or more exists inside the first chamber CBT. Since force transmitted by the internal pressure of the first chamber CBT and force transmitted by the internal pressure of the pressure transmitting layer PCLb that is in contact with the second light transmission part LTL2 are the same, the forces may be offset, and thus, a thickness Th4 of the second light transmission part LTL2 may be small.

A width of the first light transmission part LTL1 in the first direction DR1 may be defined as a third width d3, and a width of the second light transmission part LTL2 in the first direction DR1 may be defined as a fourth width d4. The third width d3 and the fourth width d4 may be different from each other. According to an embodiment of the invention, the fourth width d4 may be greater than the third width d3. Specifically, since the first light transmission part LTL1 is disposed adjacent to the light generating part LE, a surface area of the emitted light Lg may be small, and thus, the third width d3 through which the light Lg is primarily transmitted may be small. Since the second light transmission part LTL2 is farther from the light generating part LE than the first light transmission part LTL1, and the light Lg transmitted from the first light transmission part LTL1 is diffused, the fourth width d4 may be greater than the third width d3 to transmit all of the light Lg transmitted from the first light transmission part LTL2.

The relationship between the thickness Th3 and the third width d3 of the first light transmission part LTL1 according to an embodiment of the invention is as shown in Equation 1.

$$P = \frac{\partial {bt}^{2}}{25 A} \qquad Equation 1$$

In Equation 1, P is an internal pressure of the first chamber CBT, t is a thickness of the first light transmission part LTL1, A is a surface area of the first light transmission part LTL1 on the plane (i.e., in a plan view), and is allowable bending stress of the first light transmission part LTL1. When the first light transmission part LTL1 has a square shape in a plan view, A may be proportional to the square of the third width d3 of the first light transmission part LTL1, and thus, the thickness Th3 of the first light transmission part LTL1 and the third width d3 may be proportional to each other under the same pressure. Therefore, the third width d3 decreases, the thickness Th3 of the first light transmission part LTL1 may decrease. Since the thickness Th3 of the first light transmission part LTL1 is reduced by reducing the third width d3, an amount of light Lg absorbed by the first light transmission part LTL1 may be reduced. Therefore, heat generation in the first light transmission part LTL1 may be prevented, and simultaneously, transmission efficiency of the light Lg may be prevented from being deteriorated.

FIG. 9B is a cross-sectional view of a bonding apparatus according to an embodiment of the invention.

Referring to FIG. 9B, a first light transmission part LTL1a may include a first absorption prevention layer ABL1 that prevents light Lg from being absorbed therein and a first light diffusion layer LDL1 that diffuse the light Lg passing through the first absorption prevention layer ABL1. A second light transmission part LTL2a may include a second absorption prevention layer ABL2 that prevents light Lg transmitted from the first light transmission part LTL1a from being absorbed therein and a second light diffusion layer LDL2 that diffuse the light Lg passing through the second absorption prevention layer ABL2. At least one of the first light diffusion layer LDL1 or the second light diffusion layer LDL2 may include a plurality of uneven patterns UP1 and UP2. As illustrated in the drawings, the first light diffusion layer LDL1 may include a plurality of first uneven patterns UP1, and the second light diffusion layer LDL2 may include a plurality of second uneven patterns UP2.

According to an embodiment of the invention, a plurality of first through-holes Hs1 and a plurality of second through-holes Hs2 may be defined in the first absorption prevention layer ABL1 and the second absorption prevention layer ABL2, respectively. The plurality of first through-holes Hs1 defined in the first absorption prevention layer ABL1 may transmit the light Lg emitted from the light generation part LE. As the light Lg is transmitted through the plurality of first through-holes Hs1 defined in the first absorption prevention layer ABL1, an amount of light Lg absorbed by the first absorption prevention layer ABL1 may be reduced. Thus, the light Lg may be absorbed by the first absorption prevention layer ABL1 to prevent transmission efficiency of the light Lg from being deteriorated, and since the amount of light Lg absorbed is reduced, heat generation of the first light transmission part LTL1a may be reduced.

The plurality of second through-holes Hs2 defined in the second absorption prevention layer ABL2 may transmit the light Lg passing through the first light transmission part LTL1a. As the light Lg is transmitted through the plurality of second through-holes Hs2 defined in the second absorption prevention layer ABL2, an amount of light Lg absorbed by the second absorption prevention layer ABL2 may be reduced. Thus, the light Lg may be absorbed by the second absorption prevention layer ABL2 to prevent transmission efficiency of the light Lg from being deteriorated, and since the amount of light Lg absorbed is reduced, heat generation of the second light transmission part LTL2a may be reduced.

The plurality of first uneven patterns UP1 may be provided on a bottom surface of the first light diffusion layer LDL1. As the plurality of first uneven patterns UP1 are provided on the bottom surface of the first light diffusion layer LDL1, the light Lg transmitted through the first light transmission part LTL1a may be diffused. The plurality of second uneven patterns UP2 may be provided on a bottom surface of the second light diffusion layer LDL2. As the plurality of second uneven patterns UP2 are provided on the bottom surface of the second light diffusion layer LDL2, the light Lg transmitted through the second light transmission part LTL2a may be diffused.

As the first light transmission part LTL1a includes the first absorption prevention layer ABL1 and the first light diffusion layer LDL1, the heat generated from the first light transmission part LTL1a may be reduced, and the light Lg passing through the first light transmission part LTL1a may be primarily diffused. As the second light transmission part LTL2a includes the second absorption prevention layer ABL2 and the second light diffusion layer LDL2, the heat generated from the second light transmission part LTL2a may be reduced, and the light Lg passing through the second light transmission part LTL2a may be secondarily diffused so that the light Lg is irradiated with the uniform intensity onto the substrate SUBa on which at least one chip DCa is disposed. Thus, the bonding reliability between the substrate SUBa and the chip DCa may be improved. Particularly, when the plurality of chips DCa are bonded on the substrate SUBa, an amount of light Lg irradiated according to the position of the chip DCa may be prevented from varying and may be applied with intensity to the plurality of chips DCa.

According to the invention, the light transmission part may include the absorption prevention layer, in which the plurality of through-holes are defined, and the light diffusion layer that diffuses the light passing through the plurality of through-holes to reduce the heat generation in the light transmission part and uniformly irradiate the light passing through the light transmission part onto the substrate on which at least one chip is disposed. Therefore, the bonding reliability between the substrate and the chip may be improved.

It will be apparent to those skilled in the art that various modifications and deviations can be made in the invention. Thus, it is intended that the invention covers the modifications and deviations of this invention provided they come within the scope of the appended claims and their equivalents.

Accordingly, the technical scope of the invention should not be limited to the contents described in the detailed description of the specification, but should be determined by the claims.

What is claimed is:

1. A bonding apparatus comprising:
a chamber comprising a light transmission part configured to transmit light irradiated onto a substrate on which at least one chip is disposed; and
a light generation part disposed on the chamber and configured to irradiate the light,
wherein the light transmission part comprises an absorption prevention layer and a light diffusion layer,
a plurality of through-holes through which the light passes are defined in the absorption prevention layer, and
the light diffusion layer is disposed between the absorption prevention layer and the substrate to diffuse the light passing through the plurality of through-holes.

2. The bonding apparatus of claim 1, wherein the light diffusion layer comprises a plurality of uneven patterns.

3. The bonding apparatus of claim 2, wherein the light diffusion layer comprises:
a top surface adjacent to the absorption prevention layer; and
a bottom surface facing the top surface,
wherein the plurality of uneven patterns are provided on the bottom surface of the light diffusion layer.

4. The bonding apparatus of claim 1, wherein the light transmission part further comprises an upper light diffusion layer disposed on the absorption prevention layer such that the upper light diffusion layer is disposed between the light generation part and the absorption prevention layer.

5. The bonding apparatus of claim 4, wherein the upper light diffusion layer comprises a plurality of upper uneven patterns, and
the upper light diffusion layer comprises:
a bottom surface adjacent to the absorption prevention layer; and
a top surface facing the bottom surface,
wherein the plurality of upper uneven patterns are provided on the top surface of the upper light diffusion layer.

6. The bonding apparatus of claim 1, further comprising a pressure transmission layer disposed on the at least one chip in the chamber to transmit a pressure to the at least one chip.

7. The bonding apparatus of claim 6, wherein the chamber is connected to an external pressurizer outside the chamber, and
the pressure transmission layer is configured to transmit a pressure of air injected into the chamber from the external pressurizer to the at least one chip.

8. The bonding apparatus of claim 6, wherein the pressure transmission layer is connected to an external pressurizer outside the chamber, and
the pressure transmission layer is expanded by air injected into the pressure transmission layer in the chamber from the external pressurizer to transmit the pressure to the at least one chip.

9. The bonding apparatus of claim 6, further comprising a protection film disposed between the pressure transmission layer and the at least one chip.

10. The bonding apparatus of claim 1, wherein each of the plurality of through-holes has a hexagonal shape in a plan view.

11. The bonding apparatus of claim 1, wherein the absorption prevention layer has a thickness greater than a thickness of the light diffusion layer.

12. The bonding apparatus of claim 1, further comprising a foreign substance removal layer disposed around the at least one chip.

13. A bonding apparatus comprising:
a light generation part configured to irradiate light;
a first chamber comprising a first light transmission part disposed below the light generation part to transmit the light irradiated onto a substrate on which at least one chip is disposed; and
a second chamber comprising a second light transmission part disposed below the first chamber to transmit the light transmitted from the first light transmission part,
wherein the second light transmission part comprises a light diffusion layer configured to diffuse the light transmitted from the first light transmission part to the at least one chip disposed in the second chamber.

14. The bonding apparatus of claim 13, wherein a width of the first light transmission part in a direction parallel to a major surface of the substrate and a width of the second transmission part in the direction parallel to the major surface of the substrate are different from each other.

15. The bonding apparatus of claim 14, wherein the width of the second light transmission part is greater than the width of the first light transmission part.

16. The bonding apparatus of claim 13, wherein a first thickness of the first transmission part in a direction perpendicular to a major surface of the substrate is greater than a second thickness of the second light transmission part in the direction perpendicular to the major surface of the substrate.

17. The bonding apparatus of claim 13, wherein the first light transmission part comprises a first light diffusion layer configured to diffuse the light irradiated from the light generation part, and
the second light transmission part comprises a second light diffusion layer configured to diffuse the light diffused from the first light transmission part, and
wherein the second light diffusion layer comprises the light diffusion layer.

18. The bonding apparatus of claim 17, wherein at least one of the first light diffusion layer and the second light diffusion layer comprises a plurality of uneven patterns.

19. The bonding apparatus of claim 13, further comprising a pressure transmission layer disposed on the at least one chip in the second chamber to transmit a pressure to the at least one chip.

20. The bonding apparatus of claim 19, wherein the first chamber and the pressure transmission layer are connected to an external pressurizer outside the first chamber, and
the pressure transmission layer is expanded by air injected into the pressure transmission layer in the chamber from the external pressurizer to transmit the pressure to the at least one chip.
